(19) United States
(12) Patent Application Publication
(10) Pub. No.: US 2026/0010700 A1
(43) Pub. Date: Jan. 8, 2026

(54) METHODS AND SYSTEMS FOR CLOCK CONTROL LOGIC CLONING FOR MESH CLOCK

(71) Applicant: Samsung Electronics Co., Ltd., Suwon-si (KR)

(72) Inventors: Hongda Lu, Austin, TX (US); Khoa Bui, Cedar Park, TX (US)

(21) Appl. No.: 18/936,878

(22) Filed: Nov. 4, 2024

Related U.S. Application Data
(60) Provisional application No. 63/667,066, filed on Jul. 2, 2024.

(51) Int. Cl. G06F 30/396; G06F 30/3315

(52) U.S. Cl. CPC G06F 30/396; G06F 30/3315

(57) ABSTRACT

A method may include generating a first clock path, wherein a first clock control logic (CCL) is connected between a mesh and a first sequential gate. The method may include disconnecting the first CCL from the first sequential gate in the first clock path, and connecting the mesh to the first sequential gate, and generating a second clock path, wherein the mesh is connected to a second CCL. The method may include generating a first clock tree in the first clock path, the first clock tree being connected to the first sequential gate, and connecting the first CCL between the mesh and the first clock tree. Finally, the method may include generating a second clock tree in the second clock path between the second CCL and a second sequential gate.

### CROSS-REFERENCE TO RELATED APPLICATION(S)

This application claims the priority benefit under 35 U.S.C. § 119(e) of U.S. Provisional Application No. 63/667,066, filed on Jul. 2, 2024, the disclosure of which is incorporated by reference in its entirety as if fully set forth herein.

### FIELD

The disclosure generally relates to designing clock control logics. More particularly, the subject matter disclosed herein relates to improvements to methods and systems for clock control logic cloning for mesh clock.

### SUMMARY

In some digital circuit design applications, it is desirable for each block, partition, module, and/or tile in a design to operate independently from each other. For example, in a Design for Test (DfT) scan, one block may be in a shift mode while other blocks may be in capture mode. In order to accomplish this, each block may have its own clock control logic (CCL). However, a conventional mesh clock design may be unable to satisfy the requirements for designs utilize independent clock control. Accordingly, one or more embodiments of the present disclosure provide techniques to overcome such issues by cloning the CCL such that each clock tree in a block may have its own CCL. Furthermore, the embodiments of the present disclosure accomplishes these goals in such a way that existing synthesis, placement, and route flow methods may can be used with minimal modifications.

According to an embodiment of the present disclosure, a method may include: generating a first clock path, wherein a first clock control logic (CCL) is connected between a mesh and a first sequential gate; disconnecting the first CCL from the first sequential gate in the first clock path, and connecting the mesh to the first sequential gate; generating a second clock path, wherein the mesh is connected to a second CCL; generating a first clock tree in the first clock path, the first clock tree being connected to the first sequential gate, and connecting the first CCL between the mesh and the first clock tree; and generating a second clock tree in the second clock path between the second CCL and a second sequential gate.

The method may further include: connecting a first multi-source tap cell in the first clock path between the mesh and the first CCL; and connecting a second multi-source tap cell in the second clock path between the mesh and the second CCL.

The method may further include generating the second CCL by cloning the first CCL.

The first CCL may include at least a first clock and a second clock, and cloning includes cloning one of the first clock or the second clock of the first CCL.

The first CCL may include at least a first clock and a second clock, and the cloning may include cloning more than one clock of the at least the first clock and the second clock of the first CCL.

The cloning the first CCL may be performed during a register-transfer level (RTL) process.

The cloning the first CCL may be performed after an RTL process.

The first multi-source tap cell and the second multi-source tap cell may be resized or removed after the cloning the first CCL.

The cloning the first CCL may be performed at a top level or a lower level of the first clock tree or the second clock tree.

The cloning the first CCL may include cloning timing constraints of the first CCL.

According to another embodiment of the present disclosure, a system may include: a processor; and a memory storing instructions executed by the processor to cause the processor to: generate a first clock path, wherein a first clock control logic (CCL) is connected between a mesh and a first sequential gate; disconnect the first CCL from the first sequential gate in the first clock path, and connecting the mesh to the first sequential gate; generate a second clock path, wherein the mesh is connected to a second CCL; generate a first clock tree in the first clock path, the first clock tree being connected to the first sequential gate, and connecting the first CCL between the mesh and the first clock tree; and generate a second clock tree in the second clock path between the second CCL and a second sequential gate.

The system may include instructions that further cause the processor to: connect a first multi-source tap cell in the first clock path between the mesh and the first CCL; and connect a second multi-source tap cell in the second clock path between the mesh and the second CCL.

The instructions may further cause the processor to generate the second CCL by cloning the first CCL.

The first CCL may include at least a first clock and a second clock, and cloning includes cloning one of the first clock or the second clock of the first CCL.

The first CCL may include at least a first clock and a second clock, and the cloning includes cloning more than one clock of the at least the first clock and the second clock of the first CCL.

The cloning the first CCL may be performed during a register-transfer level (RTL) process.

The cloning the first CCL may be performed after an RTL process.

The first multi-source tap cell and the second multi-source tap cell may be resized or removed after the cloning the first CCL.

The cloning the first CCL may be performed at a top level or a lower level of the first clock tree or the second clock tree.

The cloning the first CCL may include cloning timing constraints of the first CCL.

According to another embodiment of the present disclosure, a circuit may include: a mesh configured to receive a clock input; a block connected to the mesh, the block including at least at a first clock path and a second clock path, wherein the first clock path includes: a first clock control logic (CCL); a first clock tree connected to the first CCL; and a first sequential gate connected to the first clock tree, and wherein the second clock path includes: a second CCL; a second clock tree connected to the second CCL; and a second sequential gate connected to the second clock tree.

The circuit may further include: a first multi-source tap cell in the first clock path between the mesh and the first CCL; and a second multi-source tap cell in the second clock path between the mesh and the second CCL.

The scope of the invention is defined by the claims, which are incorporated into this section by reference. A more complete understanding of embodiments of the invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

In the following section, the aspects of the subject matter disclosed herein will be described with reference to exemplary embodiments illustrated in the figures, in which:

FIG. 1 is a flow chart of a process for designing a digital electronic circuit, according to one or more embodiments of the present disclosure.

FIG. 2 is a block diagram of an example non-mesh clock architecture of a digital circuit.

FIG. 3 is a block diagram of an example of another non-mesh architecture of a digital circuit.

FIG. 4 is a block diagram of an example mesh clock architecture of a digital circuit.

FIG. 5 is a block diagram of an example of another mesh clock architecture digital circuit, according to one or more embodiments of the present disclosure.

FIG. 6 is a flow diagram of a process for cloning a CCL during designing of a digital circuit, according to one or more embodiments of the present disclosure.

FIG. 7 is a flow chart illustrating a method of cloning a CCL in more detail, according to one or more embodiments of the present disclosure.

FIG. 8 is a schematic diagram of an example mesh clock architecture of a digital circuit, according to one or more embodiments of the present disclosure.

FIG. 9 is a flow chart of a method for cloning CCL in a mesh clock architecture, according to one or more embodiments of the present disclosure.

FIG. 10 is a block diagram of an electronic device in a network environment, according to one or more embodiments of the present disclosure.

Embodiments of the present disclosure and their advantages are best understood by referring to the detailed description that follows. Unless otherwise noted, like reference numerals denote like elements throughout the attached drawings and the written description, and thus, descriptions thereof will not be repeated. In the drawings, the relative sizes of elements, layers, and regions may be exaggerated for clarity.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

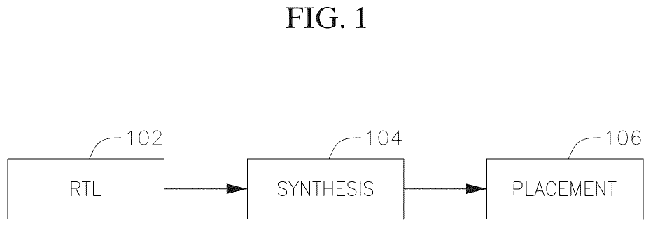

FIG. 1 is a flow chart of a process for designing a digital electronic circuit. A digital circuit may be an electronic circuit that includes synchronous circuits such as sequential gates (e.g., logic gates) and registers implemented as flip flops. Such digital circuits often include a clock signal that may be used to cycle input data (e.g., bits) through the flip flops. Clock signals may originate from a clock source such as a system-on-chip (SoC) and arrive at a clock sink, which in this case may be the flip flops that perform the operations of the circuit. The clock source may be processed by a clock control logic (CCL) that may control the operations of the clock signal. For example, the CCL may be utilized to manage the clock in a circuit, including how they are sourced, distributed, and turned on/off. CCL can source the clock from internal or external oscillators and distribute them to peripherals and modules based on their needs. A complex digital circuit may include, for example, hundreds or thousands of sequential gates. Therefore, when designing such digital circuits, the desired operation of the circuit or flow of data through the circuit may be specified during a designing process. Then, the designer (e.g., a design engineer) may utilize a computer program or a tool to determine the actual implementation of the digital components in the hardware.

In some embodiments, the designer may perform a register-transfer level (RTL) process to specify the desired operations and data flow of a circuit (operation 102). For example, the digital circuit may be a circuit or a portion of a circuit of a graphics processing unit (GPU) or central processing unit (CPU), but is not limited thereto. After the RTL process, the specified operations and data flow of the circuit design may be synthesized (operation 104), where the RTL code may be converted to a netlist. In other words, the synthesis tool may take the specification of a digital circuit designed by the designer, and determine the number of, and the types of gates, logics, and flip flops needed to achieve this operation. Then, the synthesis results may be processed by a placement tool to determine and generate a physical layout of the circuit (operation 106). Accordingly, a digital circuit may be designed according to specifications by the designer and a production ready circuit plan may be generated. One or more embodiments of the present disclosure may be directed to techniques for implementing a clock control logic in a mesh clock architecture, and thereby improving the clock signal in a digital circuit.

Although FIG. 1 illustrates various operations in a method for designing a digital electronic circuit, embodiments according to the present disclosure are not limited thereto, and according to some embodiments, the number or order of operations may vary. For example, some embodiments may include additional operations or fewer operations, or the order of operations may vary, unless otherwise stated or implied, without departing from the spirit and scope of embodiments according to the present disclosure.

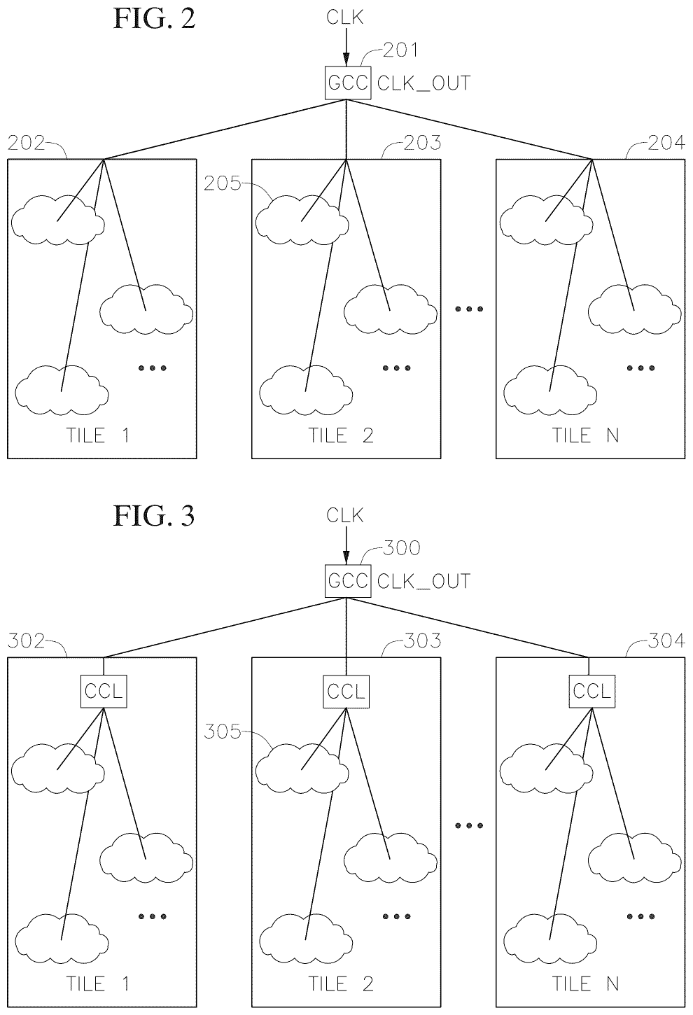

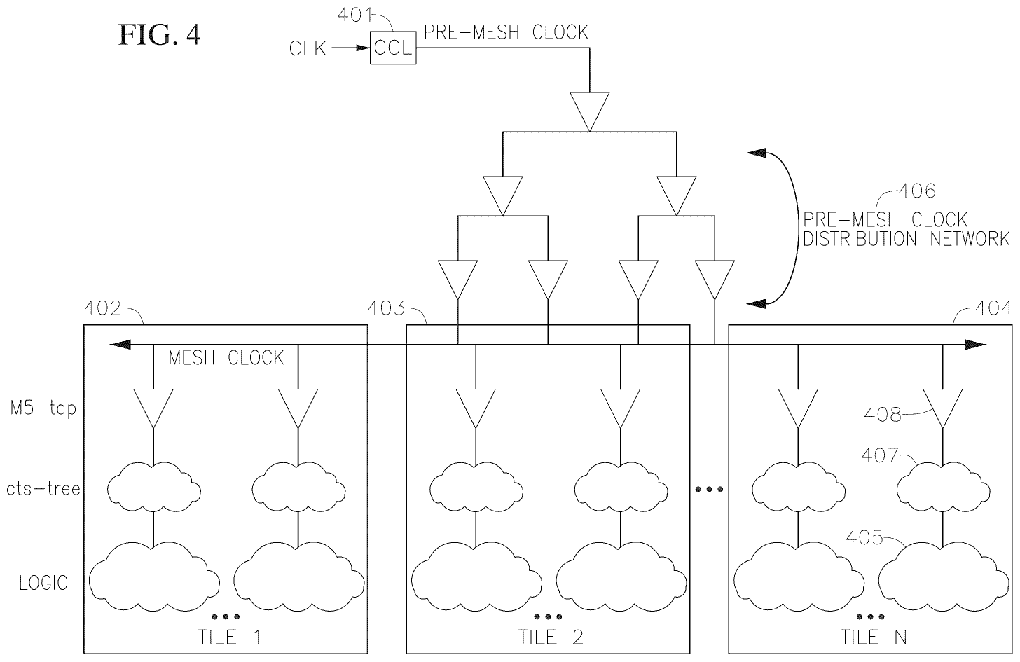

FIGS. 2-4 illustrate some of the different ways in which a clock may be distributed in a digital circuit. FIG. 2 is a block diagram of an example non-mesh clock architecture in which one CCL distributes the clock via a clock tree to each block of the plurality of blocks. FIG. 3 is a block diagram of another example of a non-mesh clock architecture in which a global clock control (GCC) distributes the clock via a clock tree to each block of the plurality of blocks, and each block of the plurality of blocks includes a separate CCL. FIG. 4 is a block diagram of an example mesh clock architecture where one CCL distributes the clock to each block of the plurality of blocks. The term “blocks” as used herein may be used interchangeably with the terms “partitions,” “modules,” and/or “tiles.”

Turning back to FIG. 2, the block diagram is a non-mesh clock architecture of a digital circuit. The circuit includes N blocks 202-204, wherein each of the blocks 202-204 includes sequential gates 205 for performing certain operations. For example, a block 202 may include a plurality of sequential gates 205 that are configured to operate and perform an operation. The operation may be cycled by a clock that is controlled by the clock control logic (CCL) 201. As shown in the configuration shown in FIG. 2, the clock may be distributed by a non-mesh configuration so the clock branches out from the CCL 201 to each of the blocks 202-204. However, because of the relatively long path from the CCL 201 to the sequential gates 205, the clock signal may be prone to on-chip variations (OCV) such that the clock received by the sequential gates 205 in the first block 202 may vary from the clock received by the sequential gates 205 in the second block 203, and so on. OCV may be mitigated by reducing the distance from the clock source to the sequential gates.

FIG. 3 illustrates a block diagram of another non-mesh architecture of a digital circuit. Similarly to FIG. 2, the circuit includes N blocks 302-304, wherein each of the blocks 302-304 includes sequential gates 305 for performing certain operations. For example, a block 302 may include a plurality of sequential gates 305 that are configured to operate and perform an operation. A global clock control 300 may be implemented as the clock source, which may distribute the clock to each of the blocks 302-304. However, different from the circuit in FIG. 2, each of the blocks 302-304 may include a separate CCL 301 to control the clock, which is then distributed to the sequential gates 305 within each block 302-304. By implementing a local CCL 301 within and for each block 302-304, the distance from the CCL 301 to the sequential gates 305 may be reduced thereby reducing clock OCV. However, because a non-mesh architecture includes only a single point of entry of the clock to the block 302-304 for the clock, CCL 301 may be easily implemented during synthesis and placement. Further improvements can be made to the clock tree by including multiple points of clock entry to each block, as may be provided in mesh clock architectures.

FIG. 4 illustrates a block diagram of a mesh clock architecture of a digital circuit. Like the circuit shown in FIG. 2, a single CCL 401 may be implemented outside of the blocks 402-404, and the clock may be distributed to the sequential gates 405 in each of the blocks 402-404 via a mesh tree. Herein the present disclosure, the term “mesh” may refer to a logic clock net that is physically implemented in a grid structure and is driven by multiple clock cells. In some embodiments, the mesh may be a multi-level H-tree 406 type mesh but is not limited thereto. Other types of trees may be possible, such as, for example, fishbone, X-tree, and multi-level trees. Accordingly, the mesh may balance the clock across all of the blocks 402-404 thereby reducing clock skews and OCV. However, differently from a non-mesh clock architecture, the mesh clock architecture provides for multiple entry points of the clock into the blocks 402-404. In other words, a single block may include a plurality clock inputs and each input may be connected to a separate clock path within the block, which is connected to a local clock tree 407 and sequential gates 405. Each of the blocks 402-404 may include a multi-source tap (mstap) cell 408, connected to the local clock tree 407, which is then connected to the sequential gates 405. The mstap cell 408 may be a buffer and the clock source or the start of the clock path. In other words, the mstap cell 408 may drive the local clock tree 407, which may then drive the sequential gates 405. It should be noted that the mstap cell 408 is optional and may be omitted, and the clock source may be the CCL 401. However, because of the relatively long path from the CCL 401 to the sequential gates 405, the clock signal may still be prone to OCV. Therefore, it may be desirable to include the CCLs in the blocks for each of the separate clock trees and sequential gates to reduce the OCV.

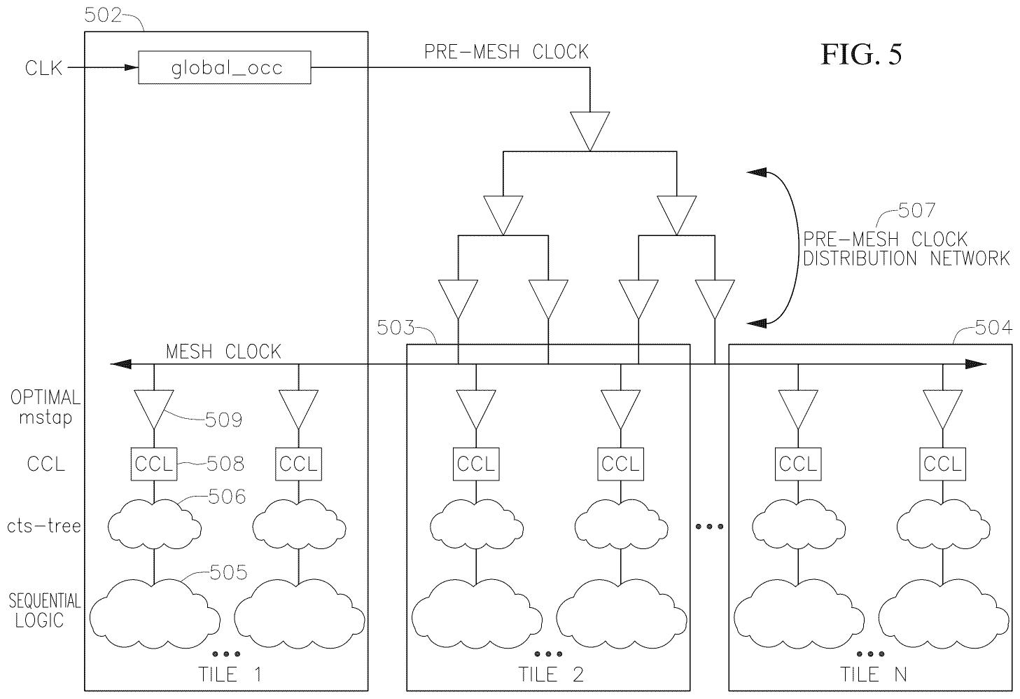

FIG. 5 illustrates a block diagram of another mesh clock architecture digital circuit. The circuit may be similar to the one shown in FIG. 4 except the CCLs are included in the blocks for each of the clock trees, and the clock is distributed from the GCL. In more detail, the circuit may include blocks 502-504, wherein each block may be configured to perform certain operations based on the logics. Accordingly, each of the blocks 502-504 may include an optional multi-source tap (mstap) cell 509, a CCL 508, a local clock tree 506, and sequential gates 505. In some embodiments, the mstap cell 509 may be connected between the CCL 508 and the mesh tree 507, and therefore the mstap cell 509 may be the start of the clock path and drive the local clock tree 506, which may then drive the sequential gates 505. In other embodiments, the CCL 508 may be connected to the mesh tree 507 directly. Therefore, the mstap cell 509 is optional and may be omitted, in which case the clock from the GCL 501 may be driven by the CCL 508.

The CCL 508 may drive the clock to the sequential gates 505 via the local clock tree 506 for each corresponding clock path. However, because the mesh configuration includes multiple points of entry for the clock signal from the GCL 501, existing tools are unable to implement multiple CCLs 508 in a single block. That is, in a non-mesh clock architecture, the clock has only a single point of entry to the block, and therefore the tools are able to implement one CCL in each block. However, in a mesh clock architecture, the clock has multiple points of entry into each block. For example, in some cases, there may be up to 20 entry points, and therefore the tools are unable to implement a clock for each clock tree in the block. Accordingly, embodiments of the present disclosure are directed to techniques for cloning the CCL in the block to each of the clock trees within that block so that each clock tree has its own CCL as shown in the circuit in FIG. 5.

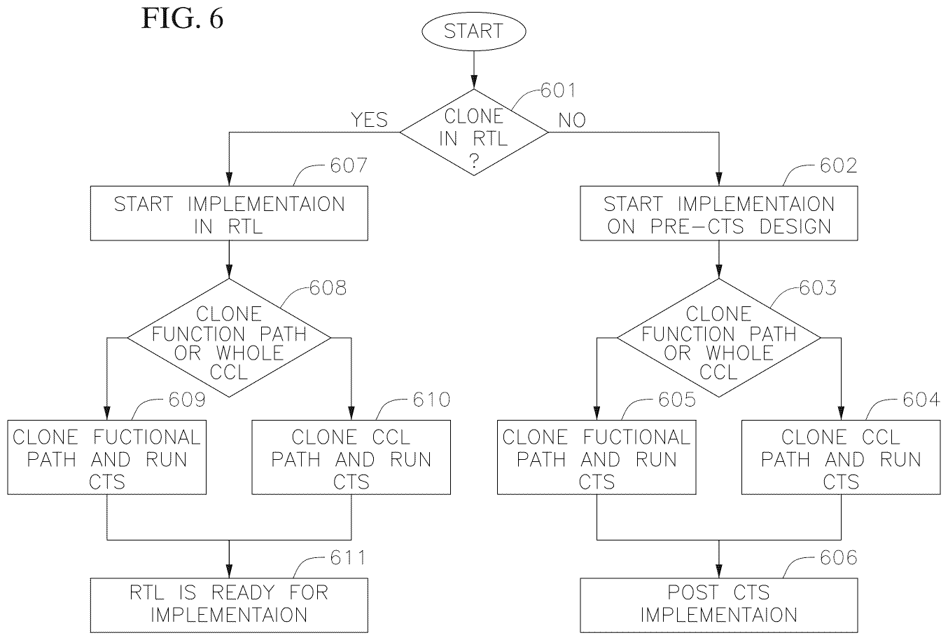

FIG. 6 is a flow diagram of a process for cloning a CCL during designing of a digital circuit. Although FIG. 6 illustrates various operations in a process for cloning the CCL, embodiments according to the present disclosure are not limited thereto, and according to some embodiments, the number or order of operations may vary. For example, some embodiments may include additional operations or fewer operations, or the order of operations may vary, unless otherwise stated or implied, without departing from the spirit and scope of embodiments according to the present disclosure.

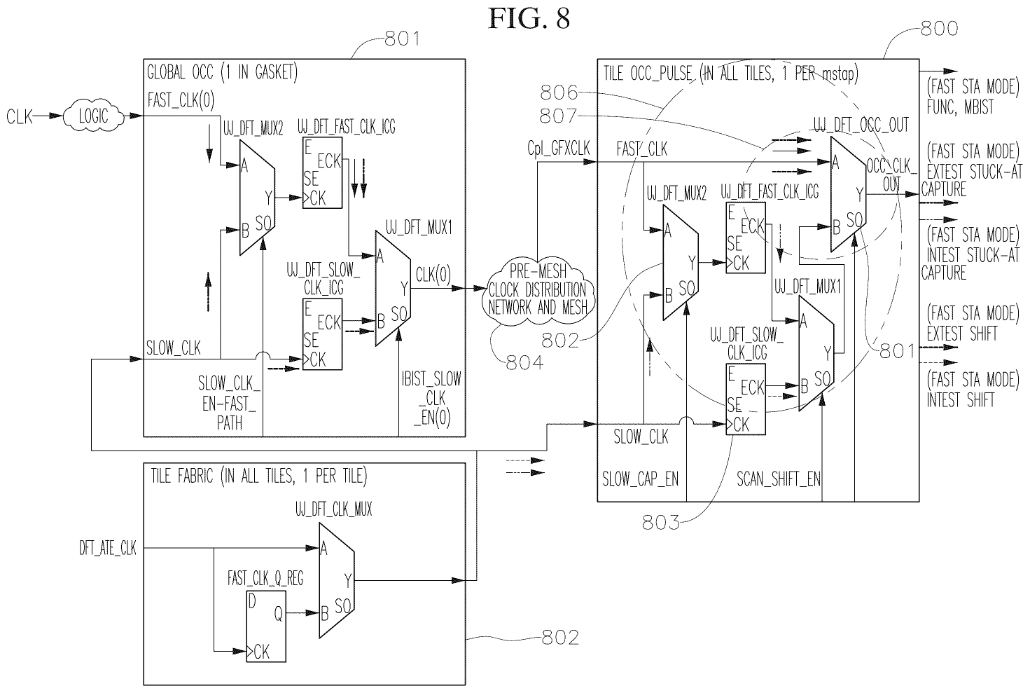

Referring back to FIG. 1, the cloning processing may be performed during or after the RTL. Therefore, the first step is determining whether the cloning will be performed during or after the RTL (operation 601). If the cloning is not performed during the RTL, then the cloning may be performed after synthesis but before the placement of the design (operation 602). Once it is determined that the cloning will be performed after the synthesis, then the next step is to determine whether just the functional path of the clock will be cloned or whether then whole CCL will be cloned (operation 603). More details regarding the functional path cloning and the whole CCL cloning will be described later with reference to FIG. 8. If it is determined to clone the functional path of the clock, then only the functional path of the block may be cloned and then the clock tree synthesis (CTS) may be performed (operation 605). On the other hand, if it is determined that the whole CCL will be cloned, then the entire CCL path may be cloned and the CTS may be performed (operation 604). Once the cloning process is completed, then placement process may be performed (operation 606).

In some embodiments, if it is determined that the cloning will be performed during RTL, then the RTL process may be commenced first (operation 607), and the closing process may be performed together with the RTL process. Then, a determination is made whether to clone just the functional path of the clock or the whole CCL (operation 610). If it is determined to clone the functional path of the clock, then only the function path of the block may be cloned and then the clock tree synthesis (CTS) may be performed (operation 609). On the other hand, if it is determined that the whole CCL will be cloned, then the entire CCL path may be cloned and the CTS may be performed (operation 610). Once the cloning process is completed, then placement may be performed (operation 611). Thus, the cloning procedures are substantially similar whether the cloning is performed during or after the RTL.

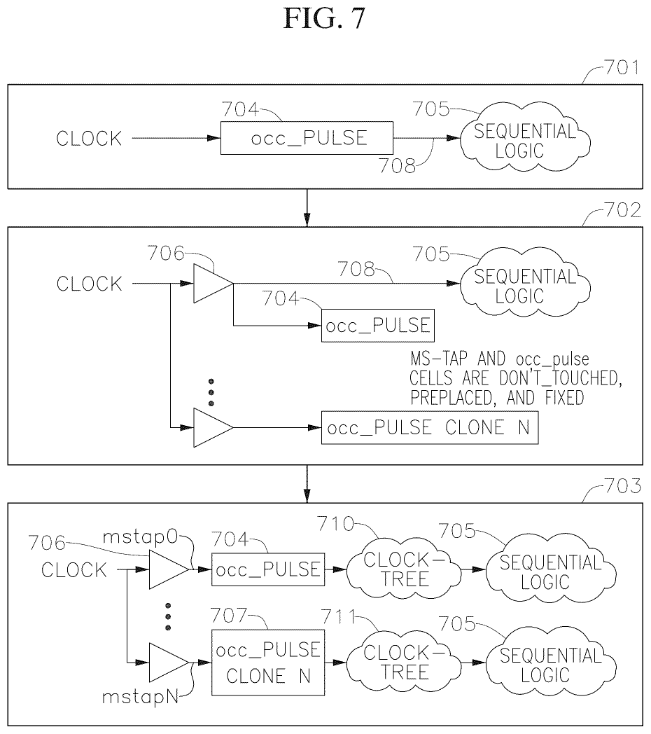

FIG. 7 is a flow chart illustrating a method of cloning a CCL in more detail, according to one or more embodiments of the present disclosure. Although FIG. 7 illustrates various operations in a method of cloning the CCL, embodiments according to the present disclosure are not limited thereto, and according to some embodiments, the number or order of operations may vary. For example, some embodiments may include additional operations or fewer operations, or the order of operations may vary, unless otherwise stated or implied, without departing from the spirit and scope of embodiments according to the present disclosure.

The method may describe the steps for cloning the CCL when it is performed after the RTL. However, as explained above, the cloning process is substantially the same even if the cloning is performed during the RTL. Therefore, the following methods may be applicable both when the cloning is performed during the RTL and after the RTL.

After the synthesis process is performed (see FIG. 1), a CCL 704 is connected directly to the sequential gates 705 in a clock path 708 so that the clock may be provided from the CCL 704 to the sequential gates 705 (operation 701). However, in a mesh clock architecture, it is desired to create clones of CCL 704 and generate multiple clockpaths 708, 709 in the block. Therefore, the first CCL 704 may be moved out of the way (e.g., removed from the path connecting to the sequential gates 705) so that the original clock path may be reused (operation 702). In other words, by removing and thereby bypassing the CCL 704 from the first clock path 708, existing flow may be utilized without making further modifications.

In some embodiments, an mstap cell 706 may be inserted into the path 708, 709 if it is desired. The mstap cell 706 may act as a buffer and be utilized to drive the CCL 704. However, it should be noted that the mstap cell 706 is optional and therefore not needed to clone the CCL 704. Accordingly, the step of adding the mstap cell 706 may be omitted. After the CCL 704 is moved out of the way, the first local clock tree 710 may be built into the first clock path 708, and a second local clock tree 711 may be built into the second clock path 709, and the CCL 704 may be moved back into the first path 708, and CCL 707 (which is a clone of the CCL 704) may be added to the second clock path 709 (operation 703). Accordingly, CCL 707 may be cloned from the original CCL 704. In some embodiments, any timing constraints such as generated clocks and clock uncertainties that may be specified for the CCL 704 may also be cloned when generating CCL 707.

FIG. 8 is a schematic diagram of an example mesh clock architecture of a digital circuit, according to one or more embodiments of the present disclosure. The digital circuit may include a GCL 801, a tile fabric 802, and a CCL 800. The GCL 801 may provide a fast clock fast_clk and the tile fabric may provide a slow clock slow_clk to the CCL 800 via a multi-level pre-mesh clock distribution network and mesh 804. However, the contents of the GCL 801 and the tile fabric 802 are not relevant for purposes of the present disclosure and therefore the details of it will not be described here in detail.

In some embodiments, the CCL 800 may include multiplexers 801, 802, and 805 configured to receive a fast clock fast_clk and/or a slow clock slow_clk. Accordingly, various different clock paths are available through the CCL 800. For example, a first clock path may be a fast clock fast_clk path 807 through multiplexer 801. Another clock path may be another fast clock fast_clk path 806 through multiplexers 802, 805, and 801. Yet another clock path may be a slow clock slow_clk path through all of the multiplexers. Thus, the CCL 800 may be used in various ways, depending on the clock paths it wants to use. Depending on the application or operation of the logic, some or all of the clocks may be utilized. Therefore, certain clock paths may desire just one or two of the clocks, whereas other clock paths may desire all of the clocks. Therefore, as mentioned earlier with reference to FIG. 6, either a functional path (e.g., one or some of the clocks) may be cloned or the entire CCL (e.g., all of the clocks) may be cloned. If the entire CCL is to be cloned, then all of the clock paths shown in block 800 may be cloned. On the other hand, if the functional path is to be cloned, then one or more of the clock paths may be cloned. Additionally, any timing constraints such as generated clocks and clock uncertainties may be included in the cloning.

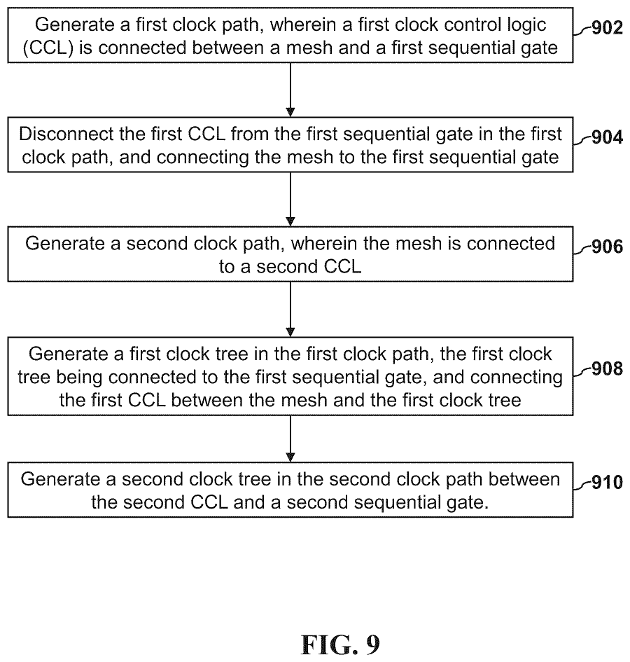

FIG. 9 is a flow chart of a method for cloning CCL in a mesh clock architecture, according to one or more embodiments of the present disclosure. Although FIG. 9 illustrates various operations in a method for cloning the CCL in a mesh clock architecture, embodiments according to the present disclosure are not limited thereto, and according to some embodiments, the number or order of operations may vary. For example, some embodiments may include additional operations or fewer operations, or the order of operations may vary, unless otherwise stated or implied, without departing from the spirit and scope of embodiments according to the present disclosure.

Referring to FIG. 9, a method for cloning a CCL may include generating a first clock path according to some embodiments. A first clock control logic (CCL) may be connected between a mesh and a first sequential gate (operation 902). Next, the first CCL may be disconnected from the first sequential gate in the first clock path, and the mesh may then be connected to the first sequential gate (operation 904). A second clock path may also be generated, and the mesh may also be connected to a second CCL (operation 906). In some embodiments, the first clock tree may be generated in the first clock path, and the first clock tree may be connected to the first sequential gate. The first CCL may be connected between the mesh and the first clock tree (operation 908). Finally, a second clock tree may be generated in the second clock path between the second CCL and a second sequential gate (operation 910). In some embodiments, a first multi-source tap cell may be connected in the first clock path between the mesh and the first CCL, and a second multi-source tap cell may be connected in the second clock path between the mesh and the second CCL.

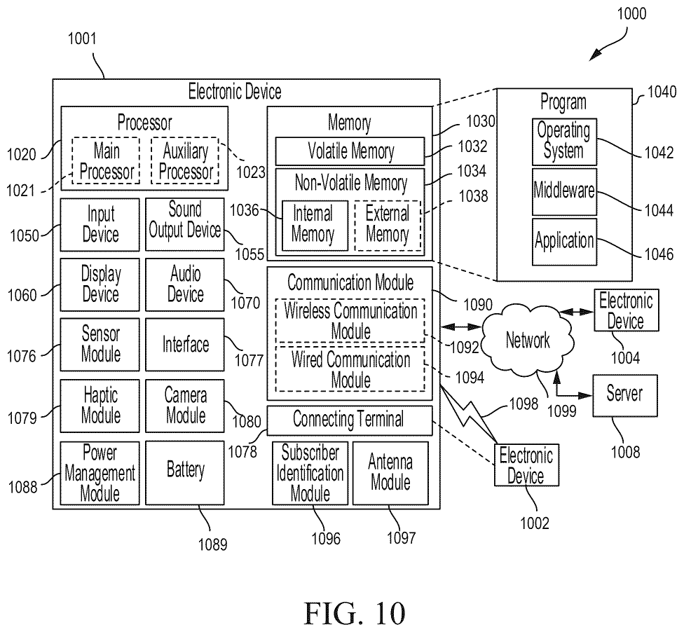

FIG. 10 is a block diagram of an electronic device in a network environment 1000, according to an embodiment. The electronic device may be a computer that may be utilized by a circuit designer such as a design engineer to design and build one or more digital circuits described according to one or more embodiments of the present disclosure.

Referring to FIG. 10, an electronic device 1001 in a network environment 1000 may communicate with an electronic device 1002 via a first network 1098 (e.g., a short-range wireless communication network), or an electronic device 1004 or a server 1008 via a second network 1099 (e.g., a long-range wireless communication network). The electronic device 1001 may communicate with the electronic device 1004 via the server 1008. The electronic device 1001 may include a processor 1020, a memory 1030, an input device 1050, a sound output device 1055, a display device 1060, an audio module 1070, a sensor module 1076, an interface 1077, a haptic module 1079, a camera module 1080, a power management module 1088, a battery 1089, a communication module 1090, a subscriber identification module (SIM) card 1096, or an antenna module 1097. In one embodiment, at least one (e.g., the display device 1060 or the camera module 1080) of the components may be omitted from the electronic device 1001, or one or more other components may be added to the electronic device 1001. Some of the components may be implemented as a single integrated circuit (IC). For example, the sensor module 1076 (e.g., a fingerprint sensor, an iris sensor, or an illuminance sensor) may be embedded in the display device 1060 (e.g., a display).

The processor 1020 may execute software (e.g., a program 1040) to control at least one other component (e.g., a hardware or a software component) of the electronic device 1001 coupled with the processor 1020 and may perform various data processing or computations.

As at least part of the data processing or computations, the processor 1020 may load a command or data received from another component (e.g., the sensor module 1076 or the communication module 1090) in volablock memory 1032, process the command or the data stored in the volablock memory 1032, and store resulting data in non-volablock memory 1034. The processor 1020 may include a main processor 1021 (e.g., a central processing unit (CPU) or an application processor (AP)), and an auxiliary processor 1023 (e.g., a graphics processing unit (GPU), an image signal processor (ISP), a sensor hub processor, or a communication processor (CP)) that is operable independently from, or in conjunction with, the main processor 1021. Additionally or alternatively, the auxiliary processor 1023 may be adapted to consume less power than the main processor 1021, or execute a particular function. The auxiliary processor 1023 may be implemented as being separate from, or a part of, the main processor 1021.

The auxiliary processor 1023 may control at least some of the functions or states related to at least one component (e.g., the display device 1060, the sensor module 1076, or the communication module 1090) among the components of the electronic device 1001, instead of the main processor 1021 while the main processor 1021 is in an inactive (e.g., sleep) state, or together with the main processor 1021 while the main processor 1021 is in an active state (e.g., executing an application). The auxiliary processor 1023 (e.g., an image signal processor or a communication processor) may be implemented as part of another component (e.g., the camera module 1080 or the communication module 1090) functionally related to the auxiliary processor 1023.

The memory 1030 may store various data used by at least one component (e.g., the processor 1020 or the sensor module 1076) of the electronic device 1001. The various data may include, for example, software (e.g., the program 1040) and input data or output data for a command related thereto. The memory 1030 may include the volablock memory 1032 or the non-volablock memory 1034. Non-volablock memory 1034 may include internal memory 1036 and/or external memory 1038.

The program 1040 may be stored in the memory 1030 as software, and may include, for example, an operating system (OS) 1042, middleware 1044, or an application 1046.

The input device 1050 may receive a command or data to be used by another component (e.g., the processor 1020) of the electronic device 1001, from the outside (e.g., a user) of the electronic device 1001. The input device 1050 may include, for example, a microphone, a mouse, or a keyboard.

The sound output device 1055 may output sound signals to the outside of the electronic device 1001. The sound output device 1055 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 1060 may visually provide information to the outside (e.g., a user) of the electronic device 1001. The display device 1060 may include, for example, a display, a hologram device, or a projector and control circuitry to control a corresponding one of the display, hologram device, and projector. The display device 1060 may include touch circuitry adapted to detect a touch, or sensor circuitry (e.g., a pressure sensor) adapted to measure the intensity of force incurred by the touch.

The audio module 1070 may convert a sound into an electrical signal and vice versa. The audio module 1070 may obtain the sound via the input device 1050 or output the sound via the sound output device 1055 or a headphone of an external electronic device 1002 directly (e.g., wired) or wirelessly coupled with the electronic device 1001.

The sensor module 1076 may detect an operational state (e.g., power or temperature) of the electronic device 1001 or an environmental state (e.g., a state of a user) external to the electronic device 1001, and then generate an electrical signal or data value corresponding to the detected state. The sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more specified protocols to be used for the electronic device 1001 to be coupled with the external electronic device 1002 directly (e.g., wired) or wirelessly. The interface 1077 may include, for example, a high-definition multimedia interface (HDMI), a universal serial bus (USB) interface, a secure digital (SD) card interface, or an audio interface.

A connecting terminal 1078 may include a connector via which the electronic device 1001 may be physically connected with the external electronic device 1002. The connecting terminal 1078 may include, for example, an HDMI connector, a USB connector, an SD card connector, or an audio connector (e.g., a headphone connector).

The haptic module 1079 may convert an electrical signal into a mechanical stimulus (e.g., a vibration or a movement) or an electrical stimulus which may be recognized by a user via tacblock sensation or kinesthetic sensation. The haptic module 1079 may include, for example, a motor, a piezoelectric element, or an electrical stimulator.

The camera module 1080 may capture a still image or moving images. The camera module 1080 may include one or more lenses, image sensors, image signal processors, or flashes. The power management module 1088 may manage power supplied to the electronic device 1001. The power management module 1088 may be implemented as at least part of, for example, a power management integrated circuit (PMIC).

The battery 1089 may supply power to at least one component of the electronic device 1001. The battery 1089 may include, for example, a primary cell which is not rechargeable, a secondary cell which is rechargeable, or a fuel cell.

The communication module 1090 may support establishing a direct (e.g., wired) communication channel or a wireless communication channel between the electronic device 1001 and the external electronic device (e.g., the electronic device 1002, the electronic device 1004, or the server 1008) and performing communication via the established communication channel. The communication module 1090 may include one or more communication processors that are operable independently from the processor 1020 (e.g., the AP) and supports a direct (e.g., wired) communication or a wireless communication. The communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication (PLC) module). A corresponding one of these communication modules may communicate with the external electronic device via the first network 1098 (e.g., a short-range communication network, such as BLUETOOTH™, wireless-fidelity (Wi-Fi) direct, or a standard of the Infrared Data Association (IrDA)) or the second network 1099 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 1092 may identify and authenticate the electronic device 1001 in a communication network, such as the first network 1098 or the second network 1099, using subscriber information (e.g., international mobile subscriber identity (IMSI)) stored in the subscriber identification module 1096.

The antenna module 1097 may transmit or receive a signal or power to or from the outside (e.g., the external electronic device) of the electronic device 1001. The antenna module 1097 may include one or more antennas, and, therefrom, at least one antenna appropriate for a communication scheme used in the communication network, such as the first network 1098 or the second network 1099, may be selected, for example, by the communication module 1090 (e.g., the wireless communication module 1092). The signal or the power may then be transmitted or received between the communication module 1090 and the external electronic device via the selected at least one antenna.

Commands or data may be transmitted or received between the electronic device 1001 and the external electronic device 1004 via the server 1008 coupled with the second network 1099. Each of the electronic devices 1002 and 1004 may be a device of a same type as, or a different type, from the electronic device 1001. All or some of operations to be executed at the electronic device 1001 may be executed at one or more of the external electronic devices 1002, 1004, or 1008. For example, if the electronic device 1001 should perform a function or a service automatically, or in response to a request from a user or another device, the electronic device 1001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 1001. The electronic device 1001 may provide the outcome, with or without further processing of the outcome, as at least part of a reply to the request. To that end, a cloud computing, distributed computing, or client-server computing technology may be used, for example.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method, comprising:
generating a first clock path, wherein a first clock control logic (CCL) is connected between a mesh and a first sequential gate;
disconnecting the first CCL from the first sequential gate in the first clock path, and connecting the mesh to the first sequential gate;
generating a second clock path, wherein the mesh is connected to a second CCL;
generating a first clock tree in the first clock path, the first clock tree being connected to the first sequential gate, and connecting the first CCL between the mesh and the first clock tree; and
generating a second clock tree in the second clock path between the second CCL and a second sequential gate.

2. The method of claim 1, further comprising:
connecting a first multi-source tap cell in the first clock path between the mesh and the first CCL; and
connecting a second multi-source tap cell in the second clock path between the mesh and the second CCL.

3. The method of claim 2, further comprising generating the second CCL by cloning the first CCL.

4. The method of claim 3, wherein the first CCL comprises at least a first clock and a second clock, and cloning comprises cloning one of the first clock or the second clock of the first CCL.

5. The method of claim 3, wherein the first CCL comprise at least a first clock and a second clock, and the cloning comprises cloning more than one clock of the at least the first clock and the second clock of the first CCL.

6. The method of claim 3, wherein the cloning the first CCL is performed during a register-transfer level (RTL) process.

7. The method of claim 3, wherein the cloning the first CCL is performed after an RTL process.

8. The method of claim 3, wherein the first multi-source tap cell and the second multi-source tap cell are resized or removed after the cloning the first CCL.

9. The method of claim 3, wherein the cloning the first CCL is performed at a top level or a lower level of the first clock tree or the second clock tree.

10. The method of claim 3, wherein the cloning the first CCL comprises cloning timing constraints of the first CCL.

11. A system comprising:
a processor; and
a memory storing instructions executed by the processor to cause the processor to:
generate a first clock path, wherein a first clock control logic (CCL) is connected between a mesh and a first sequential gate;
disconnect the first CCL from the first sequential gate in the first clock path, and connecting the mesh to the first sequential gate;
generate a second clock path, wherein the mesh is connected to a second CCL;
generate a first clock tree in the first clock path, the first clock tree being connected to the first sequential gate, and connecting the first CCL between the mesh and the first clock tree; and
generate a second clock tree in the second clock path between the second CCL and a second sequential gate.

12. The system of claim 11, wherein the instructions further cause the processor to:
connect a first multi-source tap cell in the first clock path between the mesh and the first CCL; and
connect a second multi-source tap cell in the second clock path between the mesh and the second CCL.

13. The system of claim 12, wherein the instructions further cause the processor to generate the second CCL by cloning the first CCL.

14. The system of claim 13, wherein the first CCL comprises at least a first clock and a second clock, and cloning comprises cloning one of the first clock or the second clock of the first CCL.

15. The system of claim 13, wherein the first CCL comprise at least a first clock and a second clock, and the cloning comprises cloning more than one clock of the at least the first clock and the second clock of the first CCL.

16. The system of claim 13, wherein the cloning the first CCL is performed during a register-transfer level (RTL) process.

17. The system of claim 13, wherein the cloning the first CCL is performed after an RTL process.

18. The system of claim 13, wherein the first multi-source tap cell and the second multi-source tap cell are resized or removed after the cloning the first CCL.

19. The system of claim 13, wherein the cloning the first CCL is performed at a top level or a lower level of the first clock tree or the second clock tree.

20. The system of claim 13, wherein the cloning the first CCL comprises cloning timing constraints of the first CCL.

21. A circuit, comprising:
a mesh configured to receive a clock input;
a block connected to the mesh, the block comprising at least at a first clock path and a second clock path,
wherein the first clock path comprises:
a first clock control logic (CCL);
a first clock tree connected to the first CCL; and
a first sequential gate connected to the first clock tree, and
wherein the second clock path comprises:
a second CCL;
a second clock tree connected to the second CCL; and
a second sequential gate connected to the second clock tree.

22. The circuit of claim 21, further comprising:
a first multi-source tap cell in the first clock path between the mesh and the first CCL; and
a second multi-source tap cell in the second clock path between the mesh and the second CCL.
